(19) United States
(12) Patent Application Publication
(10) Pub. No.: US 2024/0136443 A1
(43) Pub. Date: Apr. 25, 2024

(54) THIN FILM TRANSISTOR, MANUFACTURING METHOD OF THE SAME, AND DISPLAY DEVICE HAVING THE SAME

(71) Applicant: Samsung Display Co., LTD., Yongin-si (KR)

(72) Inventors: Sun Woo LEE, Yongin-si (KR); Jae Bum HAN, Yongin-si (KR); Bo Hwa KIM, Yongin-si (KR); Min Ji KIM, Yongin-si (KR)

(73) Assignee: Samsung Display Co., LTD., Yongin-si (KR)

(21) Appl. No.: 18/492,927

(22) Filed: Oct. 23, 2023

(30) Foreign Application Priority Data
Oct. 24, 2022 (KR) 10-2022-0138583

(51) Int. Cl. H01L 29/786; H01L 29/66

(52) U.S. Cl. CPC H01L 29/7869; H01L 29/66545; H01L 29/66742; H01L 29/78606; H01L 29/78693; H01L 29/78696

(57) ABSTRACT

A transistor may include a first insulating layer disposed on a substrate, a dummy layer disposed on the first insulating layer, a semiconductor layer disposed on the dummy layer, the semiconductor layer including a first area, a second area, and a channel area disposed between the first and second areas, a second insulating layer disposed on the semiconductor layer, a gate electrode overlapping the channel area with the second insulating interposed therebetween, a third insulating layer disposed over the gate electrode, a first electrode disposed on the third insulating layer, the first electrode being electrically connected to the first area, and a second electrode disposed on the third insulating layer spaced apart from the first electrode, the second electrode being electrically connected to the second area. The dummy layer may include indium oxide, and the semiconductor layer may include indium gallium zinc oxide.

### CROSS-REFERENCE TO RELATED APPLICATION(S)

This application claims priority to and benefits of Korean patent application No. 10-2022-0138583 under 35 U.S.C. § 119(a), filed on Oct. 25, 2022 in the Korean Intellectual Property Office, the entire contents of which are incorporated herein by reference.

### BACKGROUND

### 1. Technical Field

The disclosure relates to a thin film transistor, a manufacturing method of the same, and a display device having the same.

### 2. Description of the Related Art

As interest in information displays increases, research and development of display devices is continuously conducted.

### SUMMARY

Embodiments provide a transistor having an improved element characteristic and a display device having the transistor.

Embodiments also provide a manufacturing method of the above-described transistor.

In accordance with an aspect of the disclosure, there is provided a transistor that may include a first insulating layer disposed on a substrate, a dummy layer disposed on the first insulating layer, a semiconductor layer disposed on the dummy layer, the semiconductor layer including a first area, a second area, and a channel area disposed between the first and second areas, a second insulating layer disposed on the semiconductor layer, a gate electrode overlapping the channel area with the second insulating interposed therebetween, a third insulating layer disposed over the gate electrode, a first electrode disposed on the third insulating layer, the first electrode being electrically connected to the first area, and a second electrode disposed on the third insulating layer spaced apart from the first electrode, the second electrode being electrically connected to the second area. The dummy layer may include indium oxide, and the semiconductor layer may include indium gallium zinc oxide.

The semiconductor layer may include a back surface and a top surface, which face each other in a thickness direction of the substrate. The dummy layer may be disposed between the back surface of the semiconductor layer and the first insulating layer.

A width of the dummy layer and a width of the semiconductor layer may be same.

The dummy layer may have a thickness of less than about 10 nm.

The first insulating layer and the second insulating layer may include silicon oxide.

Each of the first and second insulating layers may have a hydrogen content of about 7.28E20 or less and an oxygen content of about 7.25E19 or less.

The transistor may further include an additional layer provided at an interface between the top surface of the semiconductor layer and the second insulating layer.

The transistor may further include a bottom metal pattern disposed between the substrate and the first insulating layer.

The bottom metal pattern may block light introduced into a back surface of the substrate.

In accordance with another aspect of the disclosure, there is provided a method of manufacturing a transistor. The method may include forming a first insulating layer on a substrate, forming a first base layer on the first insulating layer, forming a buffer semiconductor layer including indium gallium zinc oxide on an area of the first base layer, and forming a dummy layer by removing the first base layer not overlapping the buffer semiconductor layer, forming a second base layer on the buffer semiconductor layer and performing surface treatment, forming a second insulating layer and a gate electrode, which are sequentially stacked on the buffer semiconductor layer by forming a third base layer including a conductive material on the second base layer and removing a portion of the second and third base layers, forming a semiconductor layer by injecting an impurity into the buffer semiconductor layer, wherein the semiconductor layer is partitioned into a first area, a second area, and a channel area which is located between the first area and the second area and overlaps the gate electrode, forming a third insulating layer over the gate electrode and the semiconductor layer, and forming a first electrode and a second electrode, which are disposed on the third insulating layer spaced apart from each other. The dummy layer may include indium oxide.

The semiconductor layer may include a back surface and a top surface, which face each other in a thickness of the substrate. The dummy layer may be disposed between the back surface of the semiconductor layer and the first insulating layer.

A width of the dummy layer and a width of the semiconductor layer may be same.

The dummy layer may have a thickness of less than about 10 nm.

The first insulating layer and the second insulating layer may include silicon oxide.

Each of the first and second insulating layers may have a hydrogen content of about 7.28E20 or less and an oxygen content of about 7.25E19 or less.

The surface treatment may include an annealing process.

In the performing of the surface treatment, an additional layer may be formed at an interface between the top surface of the semiconductor layer and the second insulating layer.

In accordance with still another aspect of the disclosure, there is provided a display device that may include a light emitting element, and a transistor electrically connected to the light emitting element. The transistor may include a bottom metal pattern disposed on a substrate, a first insulating layer disposed over the bottom metal pattern, a dummy layer disposed on the first insulating layer, a semiconductor layer disposed on the dummy layer, the semiconductor layer including a first area, a second area, and a channel area disposed between the first area and the second area, a second insulating layer disposed on the semiconductor layer, a gate electrode overlapping the channel area with the second insulating layer interposed therebetween, a third insulating layer disposed over the gate electrode, a first electrode disposed on the third insulating layer, the first electrode being electrically connected to the first area, and a second electrode disposed on the third insulating layer spaced apart from the first electrode, the second electrode being electrically connected to the second area. The dummy layer may include indium oxide, and the semiconductor layer may include indium gallium zinc oxide.

The semiconductor layer may include a back surface and a top surface, which face each other in a thickness direction of the substrate. The dummy layer may be disposed between the back surface of the semiconductor layer and the first insulating layer.

The light emitting element may include a pixel electrode electrically connected to the transistor, a light emitting layer provided on the pixel electrode, and a common electrode provided over the light emitting layer.

### BRIEF DESCRIPTION OF THE DRAWINGS

FIG. 1 is a schematic plan view illustrating a transistor in accordance with one or more embodiments of the disclosure.

FIG. 2 is a schematic cross-sectional view taken along line I-I′ shown in FIG. 1.

FIG. 3 is a schematic enlarged view illustrating portion EA1 shown in FIG. 2.

FIG. 4A illustrates a transistor in accordance with one or more embodiments of the disclosure, and is a schematic cross-sectional view corresponding to the line I-I′ shown in FIG. 1.

FIG. 4B is a schematic enlarged view illustrating portion EA2 shown in FIG. 4A.

FIGS. 5 to 13 are schematic cross-sectional views illustrating a manufacturing method of a transistor in accordance with one or more embodiments of the disclosure.

FIG. 14 is a schematic plan view illustrating a display device in accordance with one or more embodiments of the disclosure.

FIG. 15 is a schematic cross-sectional view illustrating a display panel shown in FIG. 14.

FIG. 16 is a schematic circuit diagram illustrating an electrical connection relationship of components included in each of pixels shown in FIG. 14.

FIG. 17 is a schematic cross-sectional view illustrating a pixel in accordance with one or more embodiments of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

As used herein, the singular forms, “a,” “an,” and “the” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, an expression that an element such as a layer, area, substrate or plate is placed “on” or “above” another element indicates not only a case where the element is placed “directly on” or “just above” the other element but also a case where a further element is interposed between the element and the other element. An expression that an element such as a layer, area, substrate or plate is placed “beneath” or “below” another element indicates not only a case where the element is placed “directly beneath” or “just below” the other element but also a case where a further element is interposed between the element and the other element.

In this specification, it will be understood that, when an element (for example, a first element) is “(operatively or communicatively) coupled with/to” or “connected to” another element (for example, a second element), the element may be directly coupled with/to another element, or there may be an intervening element (for example, a third element) between the element and another element. Also, in this specification, the term “connection” or “coupling” may inclusively mean physical and/or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

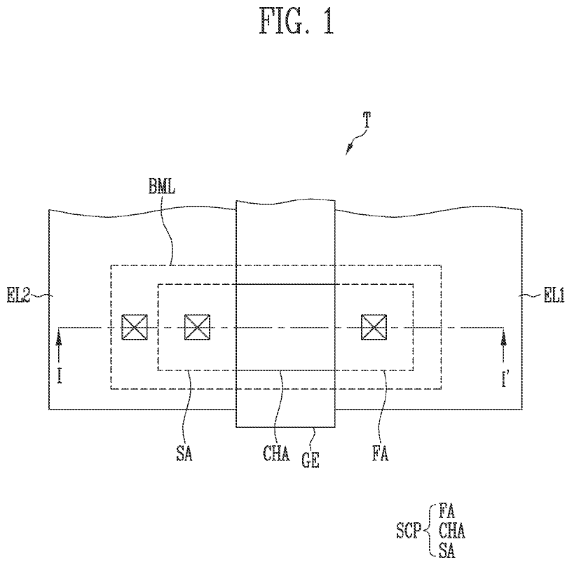

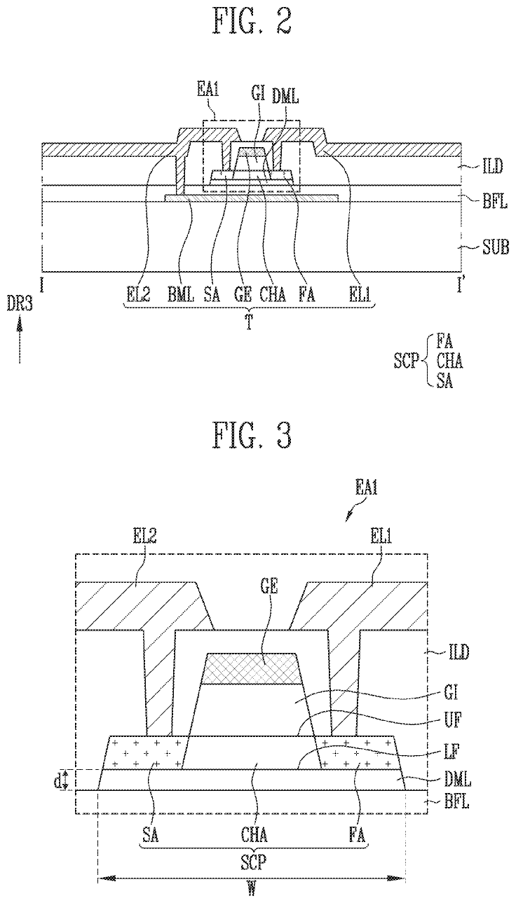

FIG. 1 is a schematic plan view illustrating a transistor T in accordance with one or more embodiments of the disclosure. FIG. 2 is a schematic cross-sectional view taken along line I-I′ shown in FIG. 1. FIG. 3 is a schematic enlarged view illustrating portion EA1 shown in FIG. 2.

For convenience of description, a vertical direction on a section is indicated as a third direction DR3.

Referring to FIGS. 1 to 3, the transistor T (a thin film transistor) in accordance with embodiments of the disclosure may include a gate electrode GE, a semiconductor layer SCP, a first electrode EL1, and a second electrode EL2. In some embodiments, the transistor T may selectively have a bottom metal pattern BML. In one or more embodiments, the transistor T may be an oxide transistor.

The semiconductor layer SCP may be disposed on a buffer layer BFL, and include a first area FA, a second area SA, and a channel area CHA (or a third area). For example, the semiconductor layer SCP may be partitioned into the first area FA, the second area SA, and the channel area CHA located between the first area FA and the second area SA. In one or more embodiments, the first area FA and a second area SA may be doped with an impurity to have conductivity. The channel area CHA may be an intrinsic semiconductor layer which overlaps gate electrode GE and is undoped with the impurity.

The channel area CHA may be an area overlapping the gate electrode GE. The first area FA may be in contact with an end of the channel area CHA and be electrically connected to the first electrode ELL The second area SA may be in contact with another end of the channel area CHA and be electrically connected to the second electrode EL2.

In one or more embodiments, the semiconductor layer SCP may include an oxide semiconductor layer. For example, the semiconductor layer SCP may include an amorphous indium gallium zinc oxide semiconductor containing a metal such as zinc oxide (ZnO), indium (In) and/or gallium (Ga). The semiconductor layer SCP may be formed through a sputtering process or the like by using an In—Ga—Zn—O-based oxide target. For example, the semiconductor layer SCP may be formed through the sputtering process in an inert gas (e.g., argon) atmosphere, an oxygen atmosphere, or a mixed atmosphere including an inert gas and oxygen, but the disclosure is not limited thereto.

An amorphous indium gallium zinc oxide semiconductor thin film formed through the sputtering process may have a complex structure in which an indium-oxide structure, a gallium-oxide structure, and a zinc-oxide structure are connected to each other. Since tendencies (or energies) in which indium, gallium, and zinc are to bind with oxygen are different from each other, an oxygen vacancy that partial binding is not made may occur. The oxygen vacancy is called a “deep level,” and may be formed in the vicinity of a valence band. An energy difference between the deep level and the valence band may be about 2.4 eV. A deep level of the amorphous indium gallium zinc oxide semiconductor thin film may have an energy level slightly higher than an energy level of the valence band. Therefore, electrons in the valence band may be in a state in which the electrons are easily changed to the deep level and be changed to the valence band. Accordingly, the amorphous indium gallium zinc oxide semiconductor thin film may have a characteristic in which the mobility of carriers of the amorphous indium gallium zinc oxide semiconductor thin film is high.

The above-described amorphous indium gallium zinc oxide semiconductor thin film may be transparent to enable a visible ray to pass therethrough, and an oxide transistor manufactured with the amorphous indium gallium zinc oxide semiconductor may have a mobility of about 1 to 100 cm2/Vs. Therefore, the amorphous indium gallium zinc oxide semiconductor thin film exhibits a high mobility characteristic as compared with amorphous silicon thin film transistors.

In one or more embodiments, the semiconductor layer SCP may include a back surface LF (or a lower surface) and a top surface UF, which face each other in a thickness direction of a substrate SUB (e.g., the third direction DR3). The back surface LF of the semiconductor layer SCP may be in contact with a dummy layer DML, and the top surface UF of the semiconductor layer SCP may be in contact with a gate insulating layer GI, the first electrode EL1, the second electrode, and an interlayer insulating layer ILD. A lower surface of the channel area CHA at the back surface LF of the semiconductor layer SCP may form a back channel part (or a first channel part) of the transistor T, and an upper surface of the channel area CHA at the top surface UF of the semiconductor layer SCP may form a front channel part (or a second channel part) of the transistor T.

The substrate SUB may include an insulative material such as glass, organic polymer, and/or quartz. The substrate SUB may be a rigid substrate or a flexible substrate.

The rigid substrate may be, for example, at least one of a glass substrate, a quartz substrate, a glass ceramic substrate, and a crystalline glass substrate.

The flexible substrate may be at least one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The buffer layer BFL may be disposed between the substrate SUB and the semiconductor layer SCP.

The buffer layer BFL (or a first insulating layer) may be disposed on the substrate SUB. The buffer layer BFL may prevent an impurity from being diffused into the semiconductor layer SCP. The buffer layer BFL may be an inorganic insulating layer including an inorganic material. The buffer layer BFL may include at least one of silicon nitride (SiNₓ), silicon oxide (SiOₓ), and silicon oxynitride (SiOₓN_{y}), or include at least one of metal oxides such as aluminum oxide (AlOₓ). In one or more embodiments, the buffer layer BFL may include silicon oxide (SiOₓ). The buffer layer BFL may be provided as a single layer, or may be provided as a multi-layer including at least two layers. In case that the buffer layer BFL is provided as the multi-layer, the layers may be formed of the same material or be formed of different materials.

In some embodiments, the bottom metal pattern BML may be disposed between the substrate SUB and the buffer layer BFL.

The bottom metal pattern BML may be a first conductive layer located between the substrate SUB and the buffer layer BFL. The bottom metal pattern BML may be electrically connected to the second electrode EL2 through a contact hole sequentially penetrating the interlayer insulating layer ILD and the buffer layer BFL. The driving range of a predetermined or selected voltage supplied to the gate electrode GE of the transistor T may be widened. The bottom metal pattern BML may be electrically connected to the second electrode EL2, to stabilize the channel area CHA of the semiconductor layer SCP. As the bottom metal pattern BML is electrically connected to the second electrode EL2, floating of the bottom metal pattern BML may be prevented.

The bottom metal pattern BML may be formed as a single layer including one appropriate (or selected) from the group consisting of copper (Cu), molybdenum (Mo), tungsten (W), aluminum neodymium (AlNd), titanium (Ti), aluminum (Al), silver (Ag), and any alloy thereof or a mixture thereof, or be formed in a double- or multi-layer structure including molybdenum (Mo), titanium (Ti), copper (Cu), aluminum (Al) or silver (Ag), which is a low-resistance material so as to decrease wiring resistance.

In one or more embodiments, the bottom metal pattern BML may overlap the semiconductor layer SCP. The bottom metal pattern BML may be used as a light blocking member for blocking light which may be introduced from a back surface of the substrate SUB, thereby protecting the transistor T. To this end, the bottom metal pattern BML may be configured with a light blocking material and/or a light absorbing material. For example, the bottom metal pattern BML may be configured as an opaque metal layer.

The gate insulating layer GI may be disposed on the semiconductor layer SCP.

The gate insulating layer GI (or a second insulating layer) may include the same material as the above-described buffer layer BFL or include an appropriate (or selected) material among the materials discussed herein as the material constituting the buffer layer BFL. In one or more examples, the gate insulating layer GI may include silicon oxide (SiOₓ). In the case of the silicon oxide (SiOₓ) constituting the gate insulating layer GI, the silicon oxide (SiOₓ) may have a hydrogen content higher than a hydrogen content of the silicon oxide (SiOₓ) constituting the buffer layer BFL.

The gate electrode GE may be disposed on the gate insulating layer GI.

The gate electrode GE may overlap the channel area CHA of the semiconductor layer SCP with the gate insulating layer GI interposed therebetween. The gate electrode GE may be made of a conductive material, e.g., a metal. The gate electrode GE may be used as a doping prevention layer for allowing an impurity not to be doped into the channel area CHA. The gate electrode GE may define the channel area CHA of the semiconductor layer SCP.

The interlayer insulating layer ILD may be disposed over the gate electrode GE.

The interlayer insulating layer ILD (or a third insulating layer) may be entirely provided and/or formed over the gate electrode GE and the buffer layer BFL. The interlayer insulating layer ILD may include the same material as the buffer layer BFL or include an appropriate (or selected) material among the materials discussed herein as the material constituting the buffer layer BFL. For example, the interlayer insulating layer ILD may be an inorganic insulating layer including an inorganic material, but the disclosure is not limited thereto. In some embodiments, the interlayer insulating layer ILD may be an organic insulating layer including an organic material. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first electrode EL1 and the second electrode EL2 may be disposed on the interlayer insulating layer ILD.

The first electrode EL1 may be located on the interlayer insulating layer ILD to overlap the first area FA of the semiconductor layer SCP, and be electrically connected to the first area FA of the semiconductor layer SCP through a contact hole penetrating an area of the interlayer insulating layer ILD. The second electrode EL2 may be located on the interlayer insulating layer ILD to overlap the second area SA of the semiconductor layer SCP, and be electrically connected to the second area SA of the semiconductor layer SCP through a contact hole penetrating another area of the interlayer insulating layer ILD.

The first electrode EL1 and the second electrode EL2 may be disposed on the interlayer insulating layer ILD over the gate electrode GE to be spaced apart from each other. One of the first electrode EL1 and the second electrode EL2 may be a source electrode, and the other of the first electrode EL1 and the second electrode EL2 may be a drain electrode.

Each of the first and second electrodes EL1 and EL2 may include a conductive material, e.g., a metal. Each of the first and second electrodes EL1 and EL2 may include the same material as the bottom metal pattern BML or include at least one material appropriate (or selected) from the materials discussed herein as the material constituting the bottom metal pattern BML.

A passivation layer for protecting the first and second electrodes EL1 and EL2 may be provided over the first and second electrodes EL1 and EL2.

The transistor T may include the dummy layer DML disposed between the back surface LF of the semiconductor layer SCP and the buffer layer BFL. In one or more embodiments, the dummy layer DML may be located on the back surface LF of the semiconductor layer SCP, e.g., the back channel part of the channel area CHA and the buffer layer BFL.

The dummy layer DML may be an inorganic insulating layer including an inorganic material. For example, the dummy layer DML may include indium oxide (IₙO₃). In one or more embodiments, the dummy layer DML may have a thickness d of less than about 10 nm, and have a width W substantially equal or similar to a width of the semiconductor layer SCP. In case that the dummy layer DML has a thickness d of about 10 nm or more, an off-current of the transistor T may increase, and therefore, an element characteristic of the transistor T may be deteriorated.

In case that the dummy layer DML including the indium oxide is located between the back channel part of the channel area CHA and the buffer layer BFL, a Fermi level variation of an energy band may occur at an interface between the channel area CHA including the amorphous indium gallium zinc oxide semiconductor and the dummy layer DML including the indium oxide, and therefore, a charge carrier density of the back channel part may increase while the content of indium at the back channel part increases. Accordingly, the electron mobility at the back channel part of the channel area CHA may be increased, so that the element characteristic of the transistor T may be improved.

In metal oxide included in an oxide semiconductor, the conductivity of the metal oxide may become higher as the composition ratio of indium becomes higher. For example, the dummy layer DML including the indium oxide may be disposed between the buffer layer BFL and the semiconductor layer SCP, thereby increasing the content of indium at the back channel part of the channel area CHA of the semiconductor layer SCP, so that the conductivity of the semiconductor layer SCP can be increased. Thus, the reliability of the transistor T may be improved due to an element characteristic of the above-described semiconductor layer SCP.

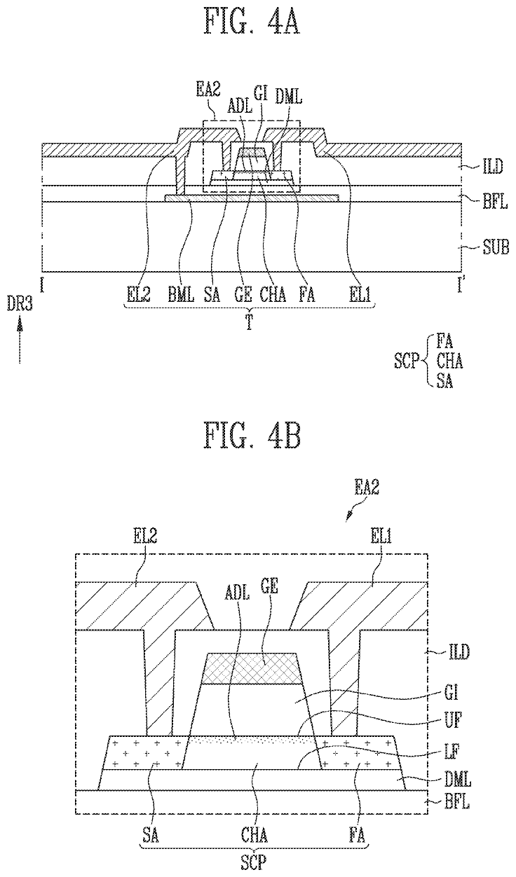

FIG. 4A illustrates a transistor T in accordance with one or more embodiments of the disclosure, and is a schematic cross-sectional view corresponding to the line I-I′ shown in FIG. 1. FIG. 4B is a schematic enlarged view illustrating portion EA2 shown in FIG. 4A.

In FIGS. 4A and 4B, portions different from those of the above-described embodiments will be described to avoid redundancy.

Referring to FIGS. 1, 4A, and 4B, the transistor T in accordance with the embodiments of the disclosure may include a gate electrode GE, a semiconductor layer SCP, a first electrode EL1, and a second electrode EL2. Also, the transistor T may include a bottom metal pattern BML and an additional layer ADL.

The semiconductor layer SCP may include a back surface LF and a top surface UF, which face each other in a thickness direction of a substrate SUB (e.g., the third direction DR3). The back surface LF of the semiconductor layer SCP may be in contact with a dummy layer DML, and the top surface UF of the semiconductor layer SCP may be in contact with a gate insulating layer GI, the first electrode EL1, the second electrode, and an interlayer insulating layer ILD. A lower surface of a channel area CHA at the back surface LF of the semiconductor layer SCP may form a back channel part (or a first channel part) of the transistor T, and an upper surface of the channel area CHA at the top surface UF of the semiconductor layer SCP may form a front channel part (or a second channel part) of the transistor T.

The additional layer ADL may be provided and/or formed at the front channel part of the transistor T.

The additional layer ADL may be formed at an interface between the semiconductor layer SCP and the gate insulating layer GI. The additional layer ADL may be formed while indium (or indium ions) is concentrated on the upper surface of the channel area CHA, e.g., the front channel part through diffusion of hydrogen, oxygen, indium, and the like at the interface between the semiconductor layer SCP and the gate insulating layer GI due to a material characteristic of each of the semiconductor layer SCP and the surface-treated gate insulating layer GI. Accordingly, the additional layer ADL may have a high indium content.

In accordance with the above-described embodiments, as the additional layer ADL having a high indium content is formed at the front channel part of the transistor T, the charge carrier density of the front channel part can increase. Accordingly, the electron mobility at the front channel part of the channel area CHA may be increased, so that the element characteristic of the transistor T may be improved.

Also, in accordance with the above-described embodiment, as the dummy layer DML including indium oxide is disposed at the back channel part of the transistor T, the charge carrier density of the back channel part may increase while the indium content at the back channel part increases. Accordingly, the electron mobility at the back channel part of the channel area CHA may be increased, so that the element characteristic of the transistor T may be improved.

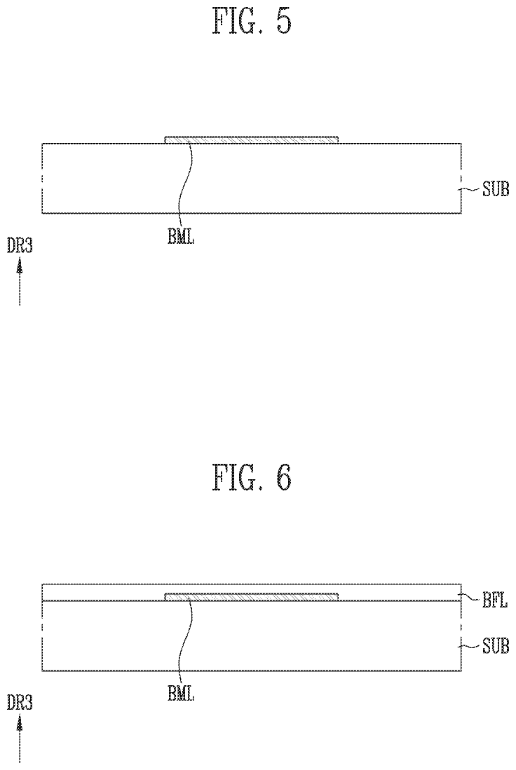

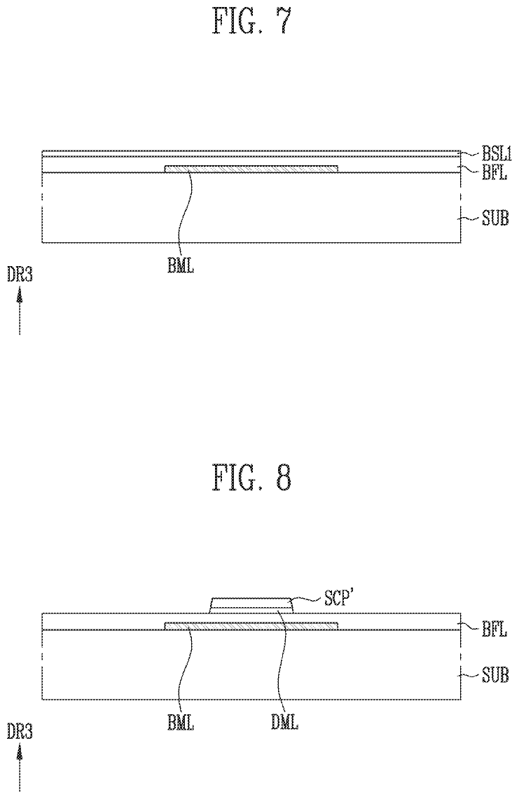

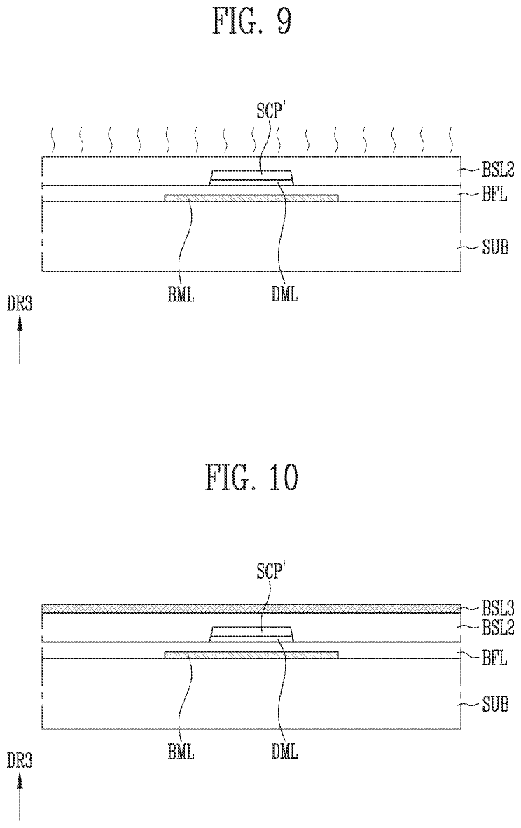

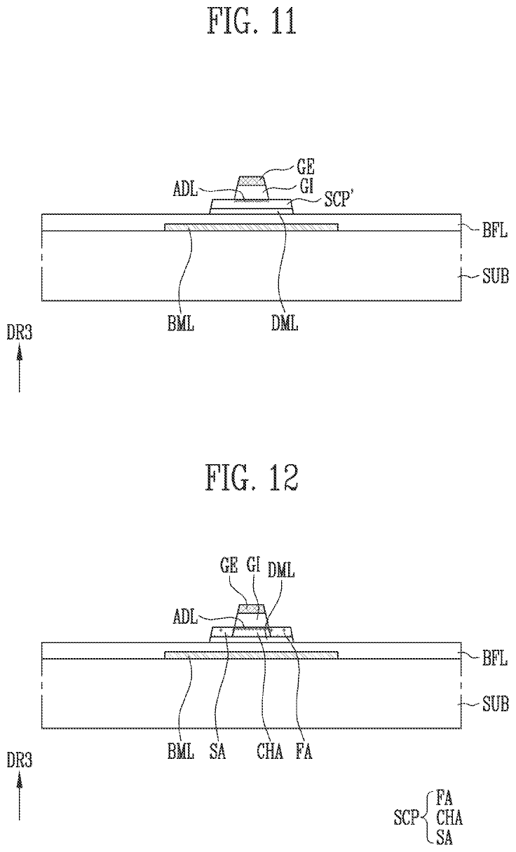

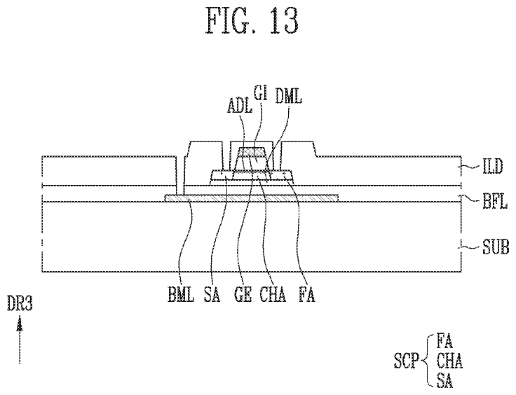

FIGS. 5 to 13 are schematic cross-sectional views illustrating a manufacturing method of a transistor in accordance with one or more embodiments of the disclosure.

Hereinafter, the manufacturing method in accordance with the embodiments of the disclosure will be sequentially described with reference to FIGS. 5 to 13.

In one or more embodiments, although it is described that manufacturing steps of the transistor are sequentially performed according to the sectional views, without changing the scope of the disclosure, some steps illustrated as being successively performed may be simultaneously performed, the sequence of the steps may be changed, some steps may be omitted, or another step may be further included between the steps.

In FIGS. 5 to 13, portions different from those of the above-described embodiments will be described to avoid redundancy.

Referring to FIGS. 1 to 5, a bottom metal pattern BML may be formed on a substrate SUB.

The substrate SUB may be a glass substrate. However, the substrate SUB may be one of other substrate, e.g., various substrates used in an ordinary semiconductor element process, such as a plastic substrate and a silicon substrate.

The bottom metal pattern BML may be formed by forming a conductive layer through a process of depositing a conductive material on a surface (or a top surface) of the substrate SUB, and patterning the conductive layer through a process such as photolithography using a mask. The conductive material may be a single kind or several kinds of metals or alloys thereof, but the disclosure is not limited thereto.

Referring to FIGS. 1 to 6, a buffer layer BFL may be formed on the bottom metal pattern BML and the substrate SUB.

The buffer layer BFL may be configured with silicon oxide (SiOₓ) in which a content of hydrogen is about 7.28E20 or less and a content of oxygen is about 7.25E19 or less. The buffer layer BFL configured with the silicon oxide may be formed through plasma enhanced chemical vapor deposition (PECVD) using silane, nitrogen oxide (N₂O), and/or the like. The buffer layer BFL may contain hydrogen. The method of forming the buffer layer BFL is not limited thereto. In some embodiments, the buffer layer BFL may be configured with silicon nitride (SiNₓ) in which a content of hydrogen is about 7.28E20 or less and a content of oxygen is about 7.25E19 or less.

The buffer layer BFL may be provided in the form of a multi-layer including two layers. For example, in case that the buffer layer BFL is configured as a double layer including a first layer and a second layer, which are sequentially stacked, the first layer and the second layer may be configured with different materials among inorganic materials, and be formed through different processes. However, the disclosure is not limited thereto. In some embodiments, the first layer and the second layer may include the same material and be formed through a continuous process.

In some embodiments, a heat treatment process may be performed after the buffer layer BFL is formed. The buffer layer BFL may include hydrogen. Since hydrogen, a hydroxyl group, moisture or the like may have influence on a semiconductor layer SCP which will be described later, its content may be reduced in advance through the heat treatment process. In the process of forming the buffer layer BFL, a temperature in a deposition chamber, an oxygen partial pressure, a time, and the like may be adjusted, thereby optimizing the hydrogen and oxygen content of the buffer layer BFL, which minimizes influence on the semiconductor layer SCP (or defect of the semiconductor layer SCP).

Referring to FIGS. 1 to 7, a first base layer BSL1 may be formed on the buffer layer BFL.

The first base layer BSL1 may be a base material of a dummy layer DML which will be described later. The first base layer BSL1 may be formed through a method of depositing an insulative material including indium oxide on the buffer layer BFL.

Referring to FIGS. 1 to 8, a buffer semiconductor layer SCP′ may be formed by forming an amorphous indium gallium zinc oxide semiconductor layer (not shown) on the first base layer BSL1 and patterning the oxide semiconductor layer through a photolithography process using a mask. The buffer semiconductor layer SCP′ may be an intrinsic semiconductor layer undoped with an impurity.

In the above-described photolithography process, a dummy layer DML may be formed by removing a portion of the first base layer BSL1, using the buffer semiconductor layer SCP′ as an etching mask. The dummy layer DML may have a width substantially equal or similar to a width of the buffer semiconductor layer SCP′.

Although a case where the dummy layer DML may be formed through a continuous process after the buffer semiconductor layer SCP′ is formed has been described in the above-described embodiment, the disclosure is not limited thereto. In order to minimize influence on the buffer semiconductor layer SCP′ in the process of forming the dummy layer DML, the buffer semiconductor layer SCP′ may be formed after the dummy layer DML is formed.

Referring to FIGS. 1 to 9, a second base layer BSL2 may be formed on the buffer semiconductor layer SCP′ and the buffer layer BFL through chemical vapor deposition or the like. For example, the second base layer BSL2 may be deposited through plasma enhanced chemical vapor deposition (PECVD) using plasma, but the disclosure is not limited thereto.

The second base layer BSL2 may be a base material of a gate insulating layer GI which will be described later. The second base layer BSL2 to be configured with silicon oxide (SiOₓ) may be formed on the buffer semiconductor layer SCP′ and the buffer layer BFL. In one or more embodiments, the second base layer BSL2 may be configured with silicon oxide (SiOₓ) in which a content of hydrogen is about 7.28E20 or less and a content of oxygen is about 7.25E19 or less. The second base layer BSL2 may have a content higher than a hydrogen content of the buffer layer BFL.

After the second base layer BSL2 is formed, surface treatment may be performed. The surface treatment may include a heat treatment process, e.g., an annealing process. A factor, e.g., a content of fluorine (F) or the like, which may have influence on a semiconductor layer SCP to be finally formed in the second base layer BSL2 through a process which will be described later may be decreased through the above-described heat treatment process. The above-described heat treatment process may soften the material of the second base layer BSL2 and may remove internal stress.

Referring to FIGS. 1 to 10, a third base layer BSL3 may be formed through a process of depositing conductive material on the second base layer BSL2. The third base layer BSL3 may be a base material of a gate electrode GE which will be described later.

The third base layer BSL3 may include at least one of copper (Cu), molybdenum (Mo), tungsten (W), aluminum neodymium (AlNd), titanium (Ti), aluminum (Al), silver (Ag), and any alloy thereof.

Referring to FIGS. 1 to 11, the gate electrode GE may be formed by patterning the third base layer BSL3 through a photolithography process using a mask. The gate electrode GE may overlap a portion of the buffer semiconductor layer SCP′. For example, the gate electrode GE may overlap a middle area of the buffer semiconductor layer SCP′. Both end portions of the buffer semiconductor layer SCP′ may be exposed to the outside.

In the above-described photolithography process, the gate insulating layer GI may be formed by removing a portion of the second base layer BSL2, using the gate electrode GE as an etching mask. The gate insulating layer GI may have a width substantially equal or similar to a width of the gate electrode GE, but the disclosure is not limited thereto. The gate electrode GE and the gate insulating layer GI located on the bottom thereof may completely overlap each other.

Due to a material characteristic of the gate insulating layer GI and the buffer semiconductor layer SCP′, which may be softened through the heat treatment, diffusion of hydrogen, oxygen, indium, and the like may readily occur at an interface between the buffer semiconductor layer SCP′ and the gate insulating layer GI, and therefore, an additional layer ADL having a high indium content may be formed while indium is concentrated on the interface (or a front channel part of a channel area CHA of the semiconductor layer SCP which will be described later).

Referring to FIGS. 1 to 12, the semiconductor layer SCP including a first area FA and a second area SA, which has conductivity, may be finally formed by doping an impurity into both the end portions of the buffer semiconductor layer SCP′ exposed to the outside. The semiconductor layer SCP may include a back surface (see “LF” shown in FIG. 4B) and a top surface (see “UF” shown in FIG. 4B), which face each other in the third direction DR3.

The semiconductor layer SCP may include the channel area CHA which is located between the first area FA and the second area SA and is undoped with the impurity while overlapping the gate electrode GE. The channel area CHA may include a back channel part located at an interface between the back surface LF of the semiconductor layer SCP and the dummy layer DML and the front channel part located at an interface between the top surface UF of the semiconductor layer SCP and the gate insulating layer GI. The additional layer ADL may be formed at the front channel part.

Referring to FIGS. 1 to 13, an interlayer insulating layer ILD may be formed on the gate electrode GE, the semiconductor layer SCP, and the buffer layer BFL.

The interlayer insulating layer ILD may be an inorganic insulating layer including an inorganic material or an organic insulating layer including an organic material. The interlayer insulating layer ILD may be partially opened to expose each of the first area FA of the semiconductor layer SCP, the second area SA of the semiconductor layer SCP, and an area of the bottom metal pattern BML.

Subsequently, a process of forming a first electrode EL1 and a second electrode EL2, which are disposed to be spaced apart from each other, may be performed on the interlayer insulating layer ILD. The first electrode EL1 may be electrically connected to the first area FA of the semiconductor layer SCP, and the second electrode EL2 may be electrically connected to the second area SA of the semiconductor layer SCP.

The transistor T manufactured through the above-described processes may be applied to various electronic devices. For example, the transistor T may be applied to a display device. The display device may include a light emitting element and a transistor electrically connected to the light emitting element. The transistor T in accordance with the above-described embodiments may be applied as the transistor.

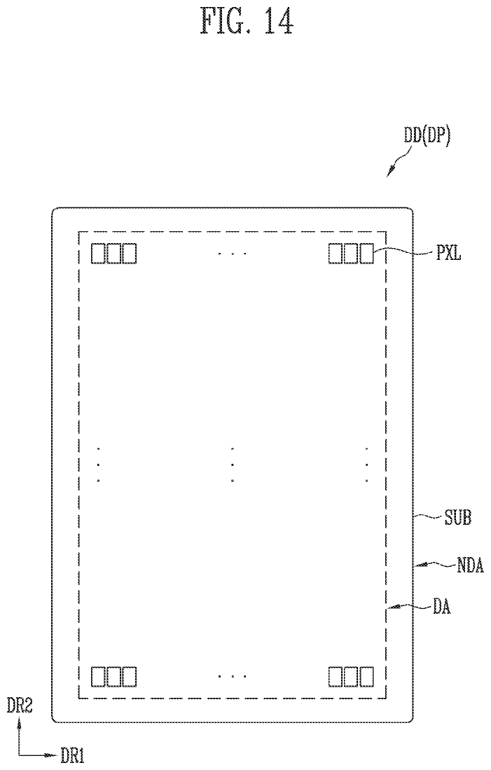

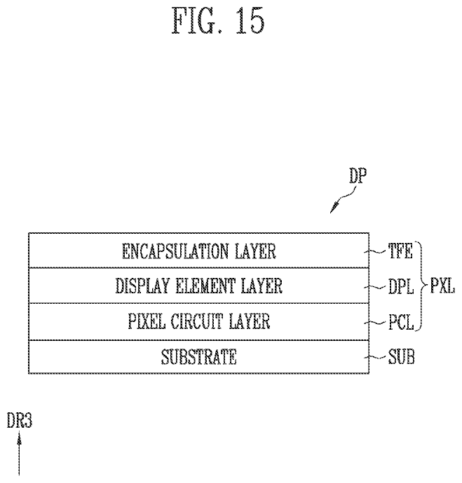

FIG. 14 is a schematic plan view illustrating a display device DD in accordance with one or more embodiments of the disclosure. FIG. 15 is a schematic cross-sectional view illustrating a display panel DP shown in FIG. 14.

In FIGS. 14 and 15, for convenience of description, a structure of the display device DD, for example, the display panel DP provided in the display device DD is briefly illustrated based on a display area DA in which an image is displayed.

Referring to FIGS. 14 and 15, the display panel DP (or the display device DD) in accordance with the embodiments of the disclosure may include a substrate SUB, pixels PXL disposed on the substrate SUB, a driver which is provided on the substrate SUB and drives the pixels PXL, and a line part electrically connecting the pixels PXL and the driver to each other.

The substrate SUB may include a transparent insulating material to enable light to be transmitted therethrough. The substrate SUB may be a rigid substrate or a flexible substrate. The substrate SUB may include the same material as the substrate SUB described with reference to FIGS. 1 and 2.

An area on the substrate SUB may be provided as the display area DA such that the pixels PXL are disposed therein, and the other area on the substrate SUB may be provided as a non-display area NDA. For example, the substrate SUB may include the display area DA including pixel areas in which the respective pixels PXL are disposed and the non-display area NDA disposed at the periphery of the display area DA (or adjacent to the display area DA).

The display area DA may have various shapes. For example, the display area DA may be provided in various shapes such as a closed polygonal including linear sides, a circle, an ellipse or the like, including a curved side, and a semicircle, a semi-ellipse or the like, including linear and curved sides.

The non-display area NDA may be provided at at least one side of the display area DA. For example, the non-display area NDA may surround a circumference of the display area DA. The driver for driving the pixels PXL and a portion of the line part (e.g., fan-out lines) connecting the pixels PXL and the driver to each other may be provided in the non-display area NDA. The non-display area NDA may correspond to a bezel area of the display device DD.

The pixels PXL may be provided in the display area DA of the substrate SUB. Each of the pixels PXL may be a minimum unit for displaying an image. Each of the pixels PXL may include a light emitting element emitting white light and/or colored light. Each of the pixels PXL may emit light of any one color among red, green, and blue. However, the disclosure is not limited thereto, and each of the pixels PXL may emit light of a color including cyan, magenta, yellow, and the like.

The pixels PXL may be arranged in a matrix form along rows (or pixel rows) extending in a first direction DR1 and columns (or pixel columns) extending in a second direction DR2 intersecting the first direction DR1. However, the arrangement form of the pixels PXL is not particularly limited, and the pixels PXL may be arranged in various forms. Although a case where the pixels PXL have a rectangular shape is illustrated in the drawing, the disclosure is not limited thereto, and the pixels PXL may be modified to have various shapes. In case that multiple pixels PXL are provided, the pixels PXL may be provided to have different areas (or sizes). For example, in the case of pixels PXL emitting lights of different colors, the pixels PXL with respect to the different colors may be provided in different areas (or sizes) or different shapes.

The driver may provide a signal and power to each pixel PXL through the line part, thereby controlling driving of the pixel PXL.

Each pixel PXL may include a pixel circuit layer PCL, a display element layer DPL, and an encapsulation layer TFE.

The pixel circuit layer PCL may be disposed on the substrate SUB, and include multiple transistors and signal lines connected to the transistors. For example, each transistor may have a form in which a semiconductor layer, a gate electrode, a first terminal, and a second terminal are sequentially stacked with an insulating layer interposed therebetween. The semiconductor layer may include an oxide semiconductor. The gate electrode, the first terminal, and the second terminal may include at least one of aluminum (Al), copper (Cu), titanium (Ti), and molybdenum (Mo), but the disclosure is not limited thereto. Also, the pixel circuit layer PCL may include at least one insulating layer.

The display element layer DPL may be disposed on the pixel circuit layer PCL. The display element layer DPL may include a light emitting element emitting light. The light emitting element may be, for example, an organic light emitting diode, but the disclosure is not limited thereto. In some embodiments, the light emitting element may be an inorganic light emitting element including an inorganic light emitting material or a light emitting element emitting light by changing a wavelength of light emitted, using a quantum dot.

The encapsulation layer TFE may be selectively disposed on the display element layer DPL. The encapsulation layer TFE may be an encapsulation substrate or have the form of an encapsulation layer provided as a multi-layer. In case that the encapsulation layer TFE has the form of the encapsulation film, the encapsulation layer TFE may include an inorganic layer and/or an organic layer. For example, the encapsulation layer TFE may have a form in which an inorganic layer, an organic layer, and an inorganic layer are sequentially stacked. The encapsulation layer TFE may prevent external air and moisture from infiltrating into the display element layer DPL and the pixel circuit layer PCL.

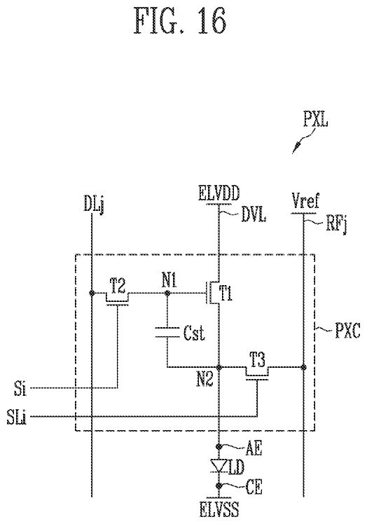

FIG. 16 is a schematic circuit diagram illustrating an electrical connection relationship of components included in each of the pixels PXL shown in FIG. 14.

Referring to FIGS. 14 to 16, the pixel PXL may include a light emitting element LD and a pixel circuit PXC electrically connected to the light emitting element LD to drive the light emitting element LD.

An anode AE of the light emitting element LD may be electrically connected to the pixel circuit PXC. The light emitting element LD may generate light (or beam) with a predetermined or selected luminance, corresponding to an amount of current supplied from the pixel circuit PXC. To this end, a second driving power source ELVSS electrically connected to a cathode CE of the light emitting element LD may be set to a voltage lower than a voltage of a first driving power source ELVDD during a driving period of the display device DD, but the disclosure is not limited thereto.

In case that the pixel PXL is located on an ith row and a jth column in the display area DA, the pixel circuit PXC of the pixel PXL may be electrically connected to an ith scan line Si and a jth data line DLj. Also, the pixel circuit PXC may be electrically connected to an ith sensing line SLi and a jth reference voltage line RFj.

The pixel circuit PXC may control an amount of current flowing from the first driving power source ELVDD to the second driving power source ELVSS via the light emitting element LD, corresponding to a data signal (or data voltage).

The pixel circuit PXC may include a first transistor T1, a second transistor T2, and a third transistor T3 and a storage capacitor Cst.

The first transistor T1 is a driving transistor for controlling a driving current applied to the light emitting element LD, and may be electrically connected between the first driving power source ELVDD and the light emitting element LD. For example, a first terminal of the first transistor T1 may be electrically connected to the first driving power source ELVDD through a driving voltage line DVL, a second terminal of the first transistor T1 may be electrically connected to a second node, and a gate electrode of the first transistor T1 may be electrically connected to a first node N1. The first transistor T1 may control an amount of driving current applied from the first driving power source ELVDD to the light emitting element LD through the second node N2 according to a voltage applied to the first node N1. In one or more embodiments, the first terminal of the first transistor T1 may be a drain electrode, and the second terminal of the first transistor T1 may be a source electrode. However, the disclosure is not limited thereto. In some embodiments, the first terminal may be the source electrode and the second terminal may be the drain electrode.

The second transistor T2 may be a switching transistor which selects a pixel PXL and activates the pixel PXL, and may be electrically connected between the jth data line DLj and the first node N1. A first terminal of the second transistor T2 may be electrically connected to the jth data line DLj, a second terminal of the second transistor T2 may be electrically connected to the first node N1, and a gate electrode of the second transistor T2 may be electrically connected to the ith scan line Si. The first terminal and the second terminal of the second transistor T2 may be different terminals. For example, in case that the first terminal is a drain electrode, and the second terminal may be a source electrode.

Therefore, the second transistor T2 may be turned on in case that a scan signal having a gate-on voltage (e.g., a high level voltage) is supplied from the ith scan line Si, to electrically connect the jth data line DLj and the first node N1 to each other. The second transistor T2 may transfer a data signal to the gate electrode of the first transistor T1.

The third transistor T3 may be turned on in case that a sensing signal is supplied from the ith sensing line SLi, to electrically connect the jth reference voltage line RFj to the first transistor T1 (or the second node N2). A first terminal of the third transistor T3 may be electrically connected to the jth reference voltage line RFj, a second terminal of the third transistor T3 may be electrically connected to the second node N2, and a gate electrode of the third transistor T3 may be electrically connected to the ith sensing line SLi.

The third transistor T3 may be a sensing transistor operated to supply a reference voltage Vref transferred through the jth reference voltage line RFj to the second node N2 or to sense a voltage or current of the second node N2 or the jth reference voltage line RFj. The reference voltage Vref may be a voltage, e.g., a voltage of an initialization power source, which is lower than the voltage of the first driving power source ELVDD and/or the data voltage.

The storage capacitor Cst may include a first storage electrode and a second storage electrode. The first storage electrode of the storage capacitor Cst may be electrically connected to the first node N1, and the second storage electrode of the storage capacitor Cst may be electrically connected to the second node N2. The storage capacitor Cst may charge a data voltage corresponding to a data signal supplied to the first node N1 during one frame period. The storage capacitor Cst may store a voltage corresponding to a difference between a voltage of the gate electrode of the first transistor T1 and a voltage of the second node N2.

In one or more embodiments, at least one of the first, second, and third transistors T1, T2, and T3 included in the pixel circuit PXC may be an oxide transistor. For example, the first transistor T1 may be implemented as an NMOS transistor including an oxide semiconductor having a low off-current.

The structure of the pixel circuit PXC may be variously modified and embodied. For example, the pixel circuit PXC may additionally further include at least one transistor element such as a transistor element for initializing the first node N1 and/or a transistor element for controlling an emission time of the light emitting element LD, or other circuit elements such as a boosting capacitor for boosting a voltage of the first node N1. For example, the pixel circuit PXC may include five transistor elements and two capacitors. In some embodiments, the pixel circuit may include seven transistor elements and two capacitors.

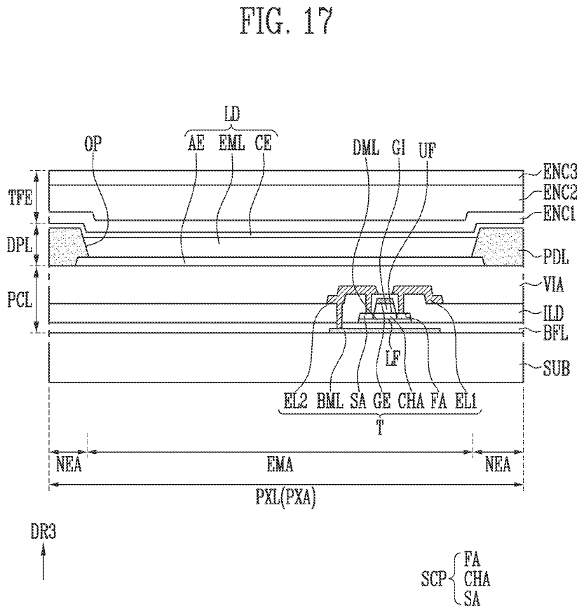

FIG. 17 is a schematic cross-sectional view illustrating a pixel PXL in accordance with one or more embodiments of the disclosure.

In FIG. 17, portions different from those of the above-described embodiments will be described to avoid redundancy.

Referring to FIGS. 14 to 17, the pixel PXL in accordance with the disclosure may be located in a pixel area PXA provided in the display area DA. The pixel area PXA may include an emission area EMA and a non-emission area NEA.

The pixel PXL may include a substrate SUB, a pixel circuit layer PCL, a display element layer DPL, and an encapsulation layer TFE.

The pixel circuit layer PCL and the display element layer DPL may be disposed on a surface of the substrate SUB to overlap each other. For example, the pixel area PXA of the substrate SUB may include the pixel circuit layer PCL disposed on the surface of the substrate SUB and the display element layer DPL disposed on the pixel circuit layer PCL. However, the mutual positions of the pixel circuit layer PCL and the display element DPL on the substrate SUB may vary in some embodiments.

The substrate SUB may include a transparent insulating material to allow light to be transmitted therethrough. The substrate SUB may be a rigid substrate or a flexible substrate.

Circuit elements (e.g., a transistor T) constituting a pixel circuit PXC and predetermined or selected signal lines electrically connected to the circuit elements may be disposed in each pixel area PXA of the pixel circuit layer PCL.

A light emitting element LD electrically connected to the pixel circuit PXC may be disposed in each pixel area PXA of the display element layer DPL.

The pixel circuit layer PCL may include a pixel circuit PXC including a transistor T and insulating layers disposed between components of the transistor T. For example, the insulating layers may include a buffer layer BFL, a gate insulating layer GI, an interlayer insulating layer ILD, and a via layer VIA, which are sequentially stacked on the substrate SUB along the third direction DR3.

The buffer layer BFL (or first insulating layer) may be entirely disposed on the substrate SUB. The buffer layer BFL may prevent an impurity from being diffused into the transistor T. The buffer layer BFL may be configured with silicon oxide (SiOₓ) in which a content of hydrogen is about 7.28E20 or less and a content of oxygen is about 7.25E19 or less.

The transistor T may be disposed on the buffer layer BFL. The transistor T may be a driving transistor for controlling a driving current of the light emitting element LD of the pixel PXL. For example, the transistor T may be the first transistor Ti described with reference to FIG. 16.

The transistor T may include a dummy layer DML, a semiconductor layer SCP, a gate electrode GE, a first electrode EL1, and a second electrode EL2. Also, the transistor T may include a bottom metal pattern BML. In one or more embodiments, the transistor T may be an oxide transistor.

The dummy layer DML may be located between the buffer layer BFL and the semiconductor layer SCP, and be configured as an inorganic insulating layer including indium oxide. The dummy layer DML may have a thickness of less than about 10 nm, and have a width substantially equal or similar to a width of the semiconductor layer SCP disposed on the top thereof.

The semiconductor layer SCP may be located between the dummy layer DML and the gate insulating layer GI. The semiconductor layer SCP may include an oxide semiconductor layer. For example, the semiconductor layer SCP may include an amorphous indium gallium zinc oxide semiconductor in which a metal such as indium (In) or gallium (Ga) is contained in zinc oxide (ZnO). The semiconductor layer SCP may include a first area FA, a second area SA, and a channel area CHA. The first area FA and the second area SA may be doped with an impurity after the gate electrode GE is formed, to have conductivity. The channel area CHA may be an intrinsic semiconductor layer which overlaps the gate electrode GE and is undoped with the impurity.

In one or more embodiments, the semiconductor layer SCP may include a back surface LF and a top surface UF, which face each other in the third direction DR3. A lower surface of the channel area CHA at the back surface LF of the semiconductor layer SCP may form a back channel part of the transistor T, and an upper surface of the channel area CHA at the top surface UF of the semiconductor layer SCP may form a front channel part of the transistor T.

In case that the dummy layer DML including indium oxide is located between the back channel part of the channel area CHA and the buffer layer BFL, a Fermi level variation of an energy band may occur at an interface between the channel area CHA and the dummy layer DML, and therefore, a charge carrier density of the back channel part may increase while the content of indium at the back channel part increases. Accordingly, the electron mobility at the back channel part of the channel area CHA may be increased, so that the element characteristic of the transistor T may be improved.

The gate insulating layer GI may be disposed on the semiconductor layer SCP.

The gate insulating layer GI (or second insulating layer) may be configured with silicon oxide (SiOₓ) in which a content of hydrogen is about 7.28E20 or less and a content of oxygen is about 7.25E19 or less. The gate insulating layer GI may have a hydrogen content higher than a hydrogen content of the buffer layer BFL, but the disclosure is not limited thereto. In case that the gate insulating layer GI is surface-treated, an additional layer (see “ADL” shown in FIG. 4A) may be formed at an interface between the gate insulating layer GI and the channel area CHA of the semiconductor layer SCP. For example, the additional layer ADL having a high indium content may be formed at the front channel part of the channel area CHA.

The gate electrode GE may be disposed on the gate insulating layer GI to be covered by the interlayer insulating layer ILD. For example, the gate electrode GE may be a gate conductive layer located between the gate insulating layer GI and the interlayer insulating layer ILD. The gate electrode GE may overlap the channel area CHA of the semiconductor layer SCP.

The interlayer insulating layer ILD may be disposed over the gate electrode GE.

The interlayer insulating layer ILD (or third insulating layer) may be entirely provided and/or formed on the gate electrode GE and the buffer layer BFL. The interlayer insulating layer ILD may be an inorganic insulating layer including an inorganic material, but the disclosure is not limited thereto. In some embodiments, the interlayer insulating layer ILD may be an organic insulating layer including an organic material.

The first electrode EL1 and the second electrode EL2 may be formed on the interlayer insulating layer ILD.

The first electrode EL1 may be disposed on the interlayer insulating layer ILD to be electrically connected to the first area FA of the semiconductor layer SCP through a contact hole penetrating the interlayer insulating layer ILD. The second electrode EL2 may be disposed on the interlayer insulating layer to be electrically connected to the second area SA of the semiconductor layer SCP through another contact hole penetrating the interlayer insulating layer ILD.

The second electrode EL2 may be electrically connected to the bottom metal pattern BML through a contact hole penetrating the interlayer insulating layer ILD and the buffer layer BFL. The second electrode EL2 may be a source electrode, and the first electrode EL1 may be a drain electrode. The bottom metal pattern BML may be identical to the bottom metal pattern BML described with reference to FIG. 2.

The via layer VIA may be entirely provided and/or formed on the first and second electrodes EL1 and EL2 and the interlayer insulating layer ILD. The via layer VIA may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In one or more embodiments, the via layer VIA may be an organic insulating layer including an organic material. The via layer VIA may be used as a planarization layer for reducing a step difference caused by components located thereunder.

In order to electrically connect the light emitting element LD and the transistor T to each other, the via layer VIA may be partially opened to expose a portion of the transistor T.

The display element layer DPL may be located on the via layer VIA.

The display element layer DPL may include the light emitting element LD and a pixel defining layer PDL.

The light emitting element LD may include a pixel electrode AE, a light emitting layer EML, and a common electrode CE. Although not directly shown in the drawing, the light emitting element LD may be electrically connected to the transistor T.

The pixel electrode AE may be provided and/or formed on the via layer VIA. The pixel electrode AE may be an anode of the light emitting element LD. The pixel electrode AE may be located in at least the emission area EMA.

The pixel electrode AE may be configured with a material having reflexibility. For example, the pixel electrode AE may be made of a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Jr), chromium (Cr), titanium (Ti), and alloys thereof. However, the material of the pixel electrode AE is not limited to the above-described embodiments. In some embodiments, the pixel electrode AE may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), and/or indium tin zinc oxide (ITZO), a conductive polymer such as poly(3,4-ethylenedioxythiophene (PEDOT), and the like. In case that the pixel electrode AE includes a transparent conductive material (or substance), a separate conductive layer may be added, which may be formed of an opaque metal for reflecting light emitted from the light emitting layer EML in an image display direction of the display device DD (or an upper direction of the encapsulation layer TFE).

The pixel defining layer PDL may be located in the non-emission area NEA, and define an emission area EMA of each pixel PXL. The pixel defining layer PDL may include an opening OP exposing an area of the pixel electrode AE. The opening OP of the pixel defining layer PDL may correspond to each emission area EMA.

The pixel defining layer PDL may be configured as an organic insulating layer including an organic material. The organic material may include acrylic resin, epoxy resin, phenolic resin, polyamide resin, polyimide resin, and/or the like. In some embodiments, the pixel defining layer PDL may include a light absorption material or have a light absorber coated thereon, to absorb light introduced from the outside. For example, the pixel defining layer PDL may include a carbon-based black pigment. However, the disclosure is not limited thereto.

The pixel defining layer PDL may protrude in the third direction DR3 from the via layer VIA along a circumference of the emission area EMA.

The light emitting layer EML may be disposed on the pixel electrode AE exposed by the opening OP of the pixel defining layer PDL.

The light emitting layer EML may be located on only the pixel electrode AE in the opening OP of the pixel defining layer PDL. The light emitting layer EML may be supplied to a desired area of a corresponding pixel PXL (e.g., the top of an area of the pixel electrode AE, which is exposed by the opening OP of the pixel defining layer PDL) through an inkjet printing process, a process using a mask, or the like, but the process of forming the light emitting layer EML is not limited thereto. The light emitting layer EML may have a multi-layer thin film structure including a light generation layer for generating light. For example, the light emitting layer EML may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. However, the disclosure is not limited thereto.

The common electrode CE may be disposed over the light emitting layer EML.

The common electrode CE may be a cathode of the light emitting element LD. The common electrode CE may be a common layer commonly provided to each pixel PXL. The common electrode CE may be provided in a plate shape throughout the display area DA. The common electrode CE may be a thin metal layer having a thickness to a degree to which light emitted from the light emitting layer EML can be transmitted therethrough. The common electrode CE may be formed of a metal material to have a relatively thin thickness or be formed of a transparent conductive material. For example, the common electrode CE may be configured with various transparent conductive materials. The common electrode CE may include at least one of various transparent conductive materials including indium tin oxide, indium zinc oxide, indium tin zinc oxide, aluminum zinc oxide, gallium zinc oxide, zinc tin oxide, and gallium tin oxide, and be formed substantially transparent or translucent to satisfy a predetermined or selected transmittance. Accordingly, light emitted from the light emitting layer EML located on the bottom of the common electrode CE may be emitted upwardly from the encapsulating layer TFE while passing through the common electrode CE.

The encapsulation layer TFE may be located on the common electrode CE.

The encapsulation layer TFE may be provided as a single layer, or be provided as a multi-layer. The encapsulation layer TFE may include multiple insulating layers covering the light emitting element LD. Specifically, the encapsulation layer TFE may include at least one inorganic layer and at least one organic layer. For example, the encapsulation layer TFE may have a structure in which an inorganic layer and an organic layer are alternately stacked. In some embodiments, the encapsulation layer TFE may be an encapsulation substrate which is disposed over the light emitting element LD and is joined with the substrate SUB through a sealant.

The encapsulation layer TFE may include first, second, and third encap layers ENC1, ENC2, and ENC3 sequentially located on the common electrode CE. The first encap layer ENC1 may be located on the display element layer DPL, thereby being located throughout the display area DA and at least a portion of the non-display area NDA. The second encap layer ENC2 may be located on the first encap layer ENC1, thereby being located throughout the display area DA and at least a portion of the non-display area NDA. The third encap layer ENC3 may be located on the second encap layer ENC2, thereby being located throughout the display area DA and at least a portion of the non-display area NDA. In some embodiments, the third encap layer ENC3 may be located throughout the whole of the display area DA and the non-display area NDA.

In one or more embodiments, each of the first and third encap layers ENC1 and ENC3 may be configured as an inorganic layer including an inorganic material, and the second encap layer ENC2 may be configured as an organic layer including an organic material. The inorganic layer may include, for example, silicon nitride (SiNₓ), silicon oxide (SiOₓ), silicon oxynitride (SiOₓN_{y}), or the like. The organic layer may include an organic insulating material such as acrylic resin, epoxy resin, phenolic resin, polyamides resin, polyimides resin, polyester resin, poly-phenylene sulfide resin, or benzocyclobutene (BCB).

In some embodiments, an optical layer including a color conversion layer and a color filter layer may be selectively disposed on the encapsulation layer TFE.

In accordance with the disclosure, a dummy layer configured with indium oxide may be formed between a buffer layer (or first insulating layer) and an oxide semiconductor layer configured with a-IGZO on a substrate, thereby improving a characteristic of a back channel part of the oxide semiconductor layer. Thus, the reliability of a transistor including the oxide semiconductor layer can be improved.

In accordance with the disclosure, after a gate insulating layer (or second insulating layer) is formed on the oxide semiconductor layer, an additional layer is formed at an interface between the oxide semiconductor layer and the gate insulating layer through surface treatment, thereby improving a characteristic of a front channel part of the oxide semiconductor layer. Thus, the reliability of the transistor including the oxide semiconductor layer can be further improved.

In accordance with the disclosure, there can be provided a display device including a transistor having improved reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A transistor, comprising:
a first insulating layer disposed on a substrate;
a dummy layer disposed on the first insulating layer;
a semiconductor layer disposed on the dummy layer, the semiconductor layer including a first area, a second area, and a channel area disposed between the first and second areas;
a second insulating layer disposed on the semiconductor layer;
a gate electrode overlapping the channel area with the second insulating interposed therebetween;
a third insulating layer disposed over the gate electrode;
a first electrode disposed on the third insulating layer, the first electrode being electrically connected to the first area; and
a second electrode disposed on the third insulating layer spaced from the first electrode, the second electrode being electrically connected to the second area, wherein
the dummy layer includes indium oxide, and
the semiconductor layer includes indium gallium zinc oxide.

2. The transistor of claim 1, wherein
the semiconductor layer includes a back surface and a top surface, which face each other in a thickness direction of the substrate, and
the dummy layer is disposed between the back surface of the semiconductor layer and the first insulating layer.

3. The transistor of claim 2, wherein a width of the dummy layer and a width of the semiconductor layer are same.

4. The transistor of claim 3, wherein the dummy layer has a thickness of less than about 10 nm.

5. The transistor of claim 2, wherein the first insulating layer and the second insulating layer include silicon oxide.

6. The transistor of claim 5, wherein each of the first and second insulating layers has a hydrogen content of about 7.28E20 or less and an oxygen content of about 7.25E19 or less.

7. The transistor of claim 6, further comprising an additional layer provided at an interface between the top surface of the semiconductor layer and the second insulating layer.

8. The transistor of claim 1, further comprising a bottom metal pattern disposed between the substrate and the first insulating layer.

9. The transistor of claim 8, wherein the bottom metal pattern blocks light introduced into a back surface of the substrate.

10. A method of manufacturing a transistor, the method comprising:
forming a first insulating layer on a substrate;
forming a first base layer on the first insulating layer;
forming a buffer semiconductor layer including indium gallium zinc oxide on an area of the first base layer, and forming a dummy layer by removing the first base layer not overlapping the buffer semiconductor layer;
forming a second base layer on the buffer semiconductor layer and performing surface treatment;
forming a second insulating layer and a gate electrode, which are sequentially stacked on the buffer semiconductor layer by forming a third base layer including a conductive material on the second base layer and removing a portion of the second and third base layers;
forming a semiconductor layer by injecting an impurity into the buffer semiconductor layer, wherein the semiconductor layer is partitioned into a first area, a second area, and a channel area which is located between the first area and the second area and overlaps the gate electrode;
forming a third insulating layer over the gate electrode and the semiconductor layer; and
forming a first electrode and a second electrode, which are disposed on the third insulating layer spaced apart from each other,
wherein the dummy layer includes indium oxide.

11. The method of claim 10, wherein
the semiconductor layer includes a back surface and a top surface, which face each other in a thickness of the substrate, and
the dummy layer is disposed between the back surface of the semiconductor layer and the first insulating layer.

12. The method of claim 11, wherein a width of the dummy layer and a width of the semiconductor layer are same.

13. The method of claim 12, wherein the dummy layer has a thickness of less than about 10 nm.

14. The method of claim 11, wherein the first insulating layer and the second insulating layer include silicon oxide.

15. The method of claim 14, wherein each of the first and second insulating layers has a hydrogen content of about 7.28E20 or less and an oxygen content of about 7.25E19 or less.

16. The method of claim 11, wherein the surface treatment includes an annealing process.

17. The method of claim 16, wherein, in the performing of the surface treatment, an additional layer is formed at an interface between the top surface of the semiconductor layer and the second insulating layer.

18. A display device, comprising:
a light emitting element; and
a transistor electrically connected to the light emitting element, wherein
the transistor includes:
a bottom metal pattern disposed on a substrate;
a first insulating layer disposed over the bottom metal pattern;
a dummy layer disposed on the first insulating layer;
a semiconductor layer disposed on the dummy layer, the semiconductor layer including a first area, a second area, and a channel area disposed between the first area and the second area;
a second insulating layer disposed on the semiconductor layer;
a gate electrode overlapping the channel area with the second insulating layer interposed therebetween;
a third insulating layer disposed over the gate electrode;
a first electrode disposed on the third insulating layer, the first electrode being electrically connected to the first area; and
a second electrode disposed on the third insulating layer spaced apart from the first electrode, the second electrode being electrically connected to the second area, and
the dummy layer includes indium oxide, and the semiconductor layer includes indium gallium zinc oxide.

19. The display device of claim 18, wherein
the semiconductor layer includes a back surface and a top surface, which face each other in a thickness direction of the substrate, and
the dummy layer is disposed between the back surface of the semiconductor layer and the first insulating layer.

20. The display device of claim 19, wherein the light emitting element includes:
a pixel electrode electrically connected to the transistor;
a light emitting layer provided on the pixel electrode; and
a common electrode provided over the light emitting layer.
